(19) United States
(12) Patent Application Publication
(10) Pub. No.: US 2009/0086421 A1
(43) Pub. Date: Apr. 2, 2009

(54) FINE-PITCH, SPLAY-RESISTANT, FINGER-TO-FINGER CONTACT-CAPABLE, HDD EMI SHIELD

(75) Inventors: Timothy W. Olesiewicz, Dublin, CA (US); Brett C. Ong, San Jose, CA (US); William A. De Meulenaere, Newark, CA (US)

Correspondence Address: OSHA LIANG L.L.P./SUN, TWO HOUSTON CENTER, 909 FANNIN, SUITE 3500, HOUSTON, TX, 77010, US

(73) Assignee: Sun Microsystems, Inc., Santa Clara, CA (US)

(21) Appl. No.: 11/862,921

(22) Filed: Sep. 27, 2007

(51) Int. Cl. G06F 1/16; H05K 7/14; H05K 9/00

(52) U.S. Cl. 361/679.33; 312/223.2; 361/818

(57) ABSTRACT

An electromagnetic interference shield for a hard disk drive has a metal shield portion, a plurality of top fingers, bottom fingers, left fingers, and right fingers disposed on four sides of the metal shield portion, and bars tying the tips of the plurality of top fingers together, the tips of the plurality of bottom fingers together, the tips of the plurality of right fingers together, and the tips of the plurality of left fingers together. Each of the plurality of top fingers and bottom fingers are wider than each of the plurality of left fingers and right fingers. Each of the plurality of top fingers, bottom fingers, left fingers, and right fingers has a perpendicular jog at a base portion thereof.

### BACKGROUND OF INVENTION

1. Field of the Invention

The invention generally relates to a hard disk drive electromagnetic interference shield for a blade server.

2. Background Art

FIG. 1 shows a typical computer server rack 10 with blade server modules 15 disposed therein. Each blade server module 15 generally has at least a hard disk drive bracket 20 with a hard disk drive disposed therein. In other cases, the hard disk drive bracket 20 may be disposed directly into the server rack 10 without a blade server module 15.

A blade server module designed by Sun Microsystems, Inc. is shown in FIGS. 2 and 3. In order to reduce electromagnetic interference (“EMI”), a blade server module has a Small Form Factor (“SFF”) hard disk drive (“HDD”) EMI shield 10 disposed between the front bezel and the hard disk drive. The SFF HDD EMI shield 10 shown in FIGS. 2 and 3 has a shield portion which is hidden behind the front bezel, numerous small top fingers 19 and side fingers 18, and a side portion 17. The SFF HDD EMI shield 10 protects the HDD from electromagnetic interference, which is radiated or conducted energy that can disrupt or degrade performance of the HDD. The SFF HDD EMI shield 10 does not allow for finger-to-finger contact, and is prone to splaying/peeling and damage from handling. The SFF HDD EMI shield 10 also limits the number of hard disk drives that can be integrated into the blade servers modules 15.

### SUMMARY OF INVENTION

In one or more embodiments of the present invention, an electromagnetic interference shield for a hard disk drive comprises a metal shield portion, a plurality of top fingers, bottom fingers, left fingers, and right fingers disposed on four sides of the metal shield portion, and bars tying the tips of the plurality of top fingers together, the tips of the plurality of bottom fingers together, the tips of the plurality of right fingers together, and the tips of the plurality of left fingers together. Each of the plurality of top fingers and bottom fingers are wider than each of the plurality of left fingers and right fingers. Each of the plurality of top fingers, bottom fingers, left fingers, and right fingers has a perpendicular jog at a base portion thereof.

In one or more embodiments of the present invention, a hard disk drive bracket comprises a front bezel, a back bracket disposed behind the front bezel, a hard disk drive disposed in the back bracket, and an electromagnetic interference shield disposed between the front bezel and the back bracket. The electromagnetic interference shield comprises a metal shield portion, a plurality of top fingers, bottom fingers, left fingers, and right fingers disposed on four sides of the metal shield portion, and bars tying the tips of the plurality of top fingers together, the tips of the plurality of bottom fingers together, the tips of the plurality of right fingers together, and the tips of the plurality of left fingers together. Each of the plurality of top fingers and bottom fingers are wider than each of the plurality of left fingers and right fingers. Each of the plurality of top fingers, bottom fingers, left fingers, and right fingers has a perpendicular jog at a base portion thereof.

Other aspects and advantages of the invention will be apparent from the following description and the appended claims.

### BRIEF DESCRIPTION OF DRAWINGS

FIG. 1 shows a computer server rack with computer servers disposed therein.

FIG. 2 shows a HDD bracket having a SFF HDD EMI shield.

FIG. 3 shows a HDD bracket having a SFF HDD EMI shield.

FIG. 4 shows a perspective view of a HDD EMI shield according to one or more embodiments of the present invention.

FIG. 5 shows a side view of a HDD EMI shield according to one or more embodiments of the present invention.

FIG. 6 shows a perspective view of a HDD bracket having a HDD EMI shield according to one or more embodiments of the present invention.

FIG. 7 shows a side view of a HDD bracket having a HDD EMI shield according to one or more embodiments of the present invention.

FIG. 8 shows a top view of a HDD bracket having a HDD EMI shield according to one or more embodiments of the present invention.

FIG. 9 shows a bottom view of a HDD bracket having a HDD EMI shield according to one or more embodiments of the present invention.

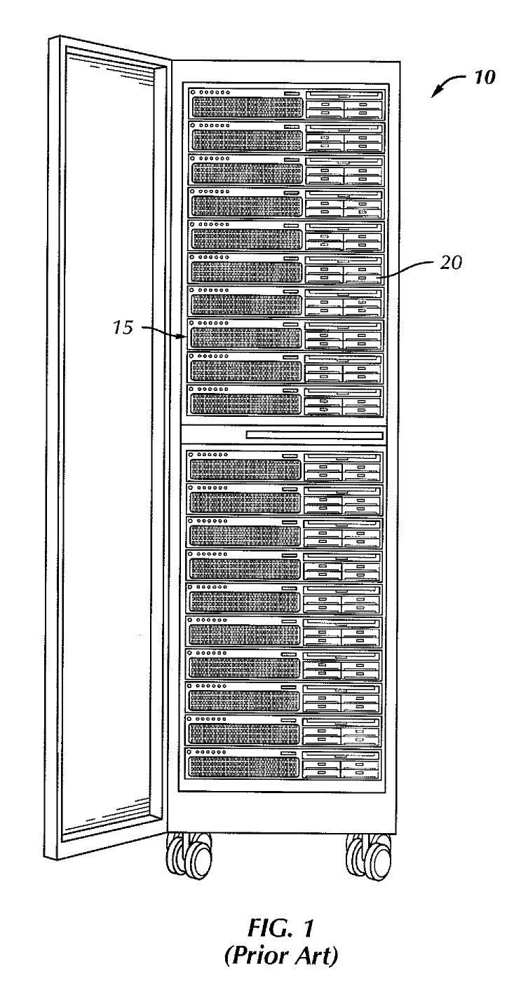

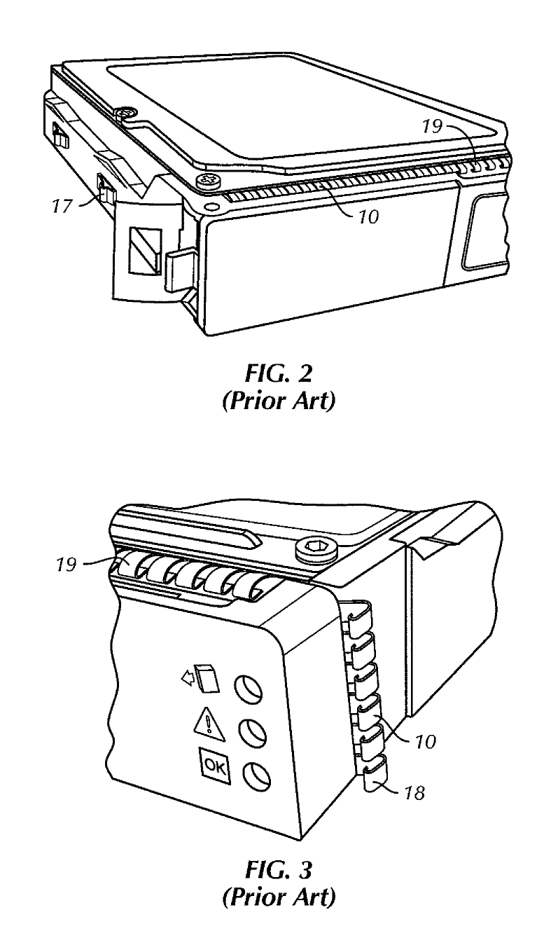

### DETAILED DESCRIPTION

Exemplary embodiments of the invention will be described with reference to the accompanying figures. Like items in the figures are shown with the same reference numbers.

In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

Embodiments of the invention relate to a hard disk drive (“HDD”) electromagnetic interference (“EMI”) shield. More specifically, one or more embodiments of the invention relate to a fine-pitch, splay-resistant, and finger-to-finger contact-capable HDD EMI shield.

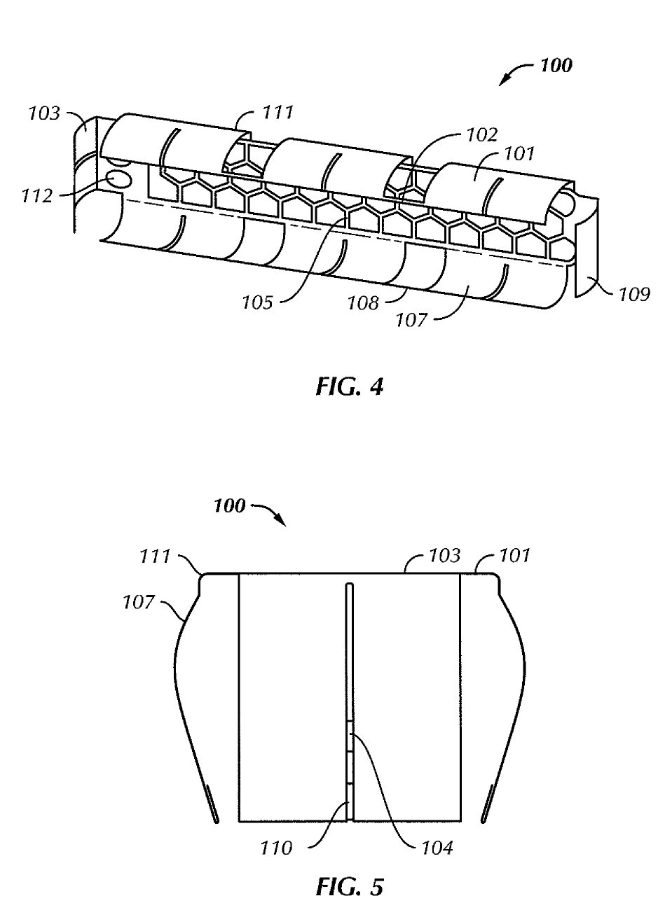

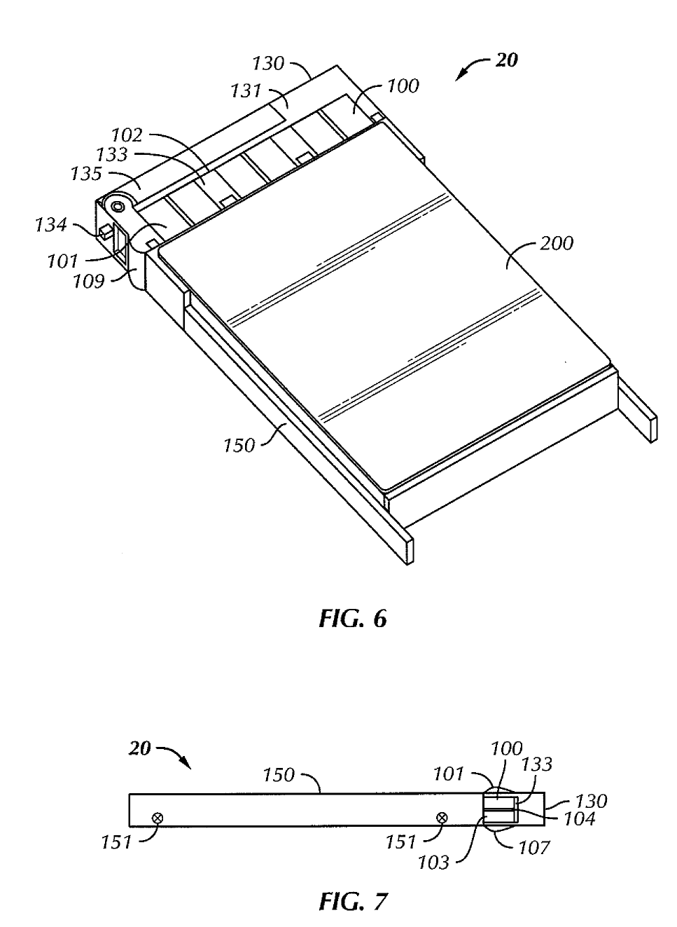

FIG. 4 shows a perspective view, and FIG. 5 shows a side view, of an HDD EMI shield 100 according to one or more embodiments of the present invention. The HDD EMI shield 100 includes a metal shield 105 with six wide top fingers 101, six wide bottom fingers 107, two left fingers 103, and two side fingers 109. The metal shield 105 shown has a hexagonal tiling pattern, however, the pattern can also be any other metal shield pattern known in the art. The top fingers 101 and bottom fingers 107 are wider than the left fingers 103 and the right fingers 109 so as to fit on the side of the HDD bracket 20. This is because, particularly in the case of a small form factor (“SFF”) devices, the HDD bracket 20 on which the HDD EMI shield 100 is disposed is necessarily thin. Although the top fingers 101, bottom fingers 107, and left fingers 103 are the same length, the right fingers 109 are shorter to allow for a latch 134 on the HDD bracket 20, which will be explained later with reference to FIGS. 6-9.

The top fingers 101, bottom fingers 107, left fingers 103, and right fingers 109 are connected by thin bars 102, 108, 104, 110 at the tip end of the top fingers 101. Each of the top fingers 101, bottom fingers 107, left fingers 103, and right fingers 109 are curved towards the metal shield 105, and has a substantially perpendicular jog 111 as each finger extends from the metal shield 105. The perpendicular shape of the jog 111 has the advantage of, for example, preventing splaying. On one side of the HDD EMI shield 100 are disposed apertures 112 for indicator lights, e.g., light emitted diodes or light pipes, to pass through.

In one or more embodiments of the present invention, the metal shield 105 may be tin plated. In one or more embodiments of the present invention, may be manufactured from beryllium copper or recyclable clean copper. In one or more embodiments, the HDD EMI shield is manufactured from a 0.07 mm thick material.

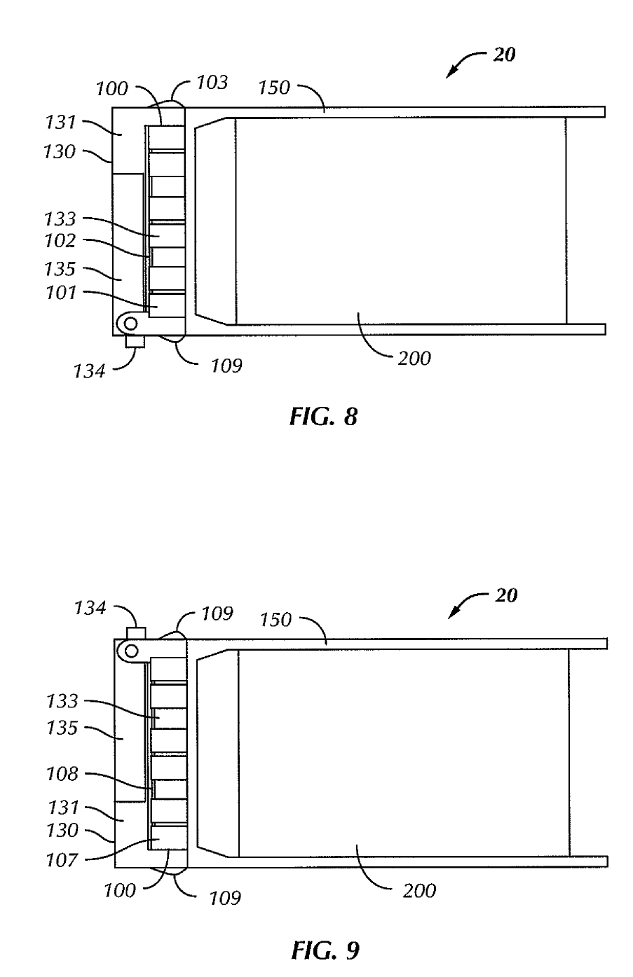

FIG. 6 shows a perspective view of a HDD bracket 20 having a HDD EMI shield 100 according to one or more embodiments of the present invention. FIG. 7 shows a side view, FIG. 8 shows a top view, and FIG. 9 shows a bottom view, of a HDD bracket 20 having a HDD EMI shield 100 according to one or more embodiments of the present invention. The HDD bracket 20 consists of a front bezel 130, back bracket 150 disposed behind the front bezel 130, a HDD 200 disposed in the back bracket 150, and a HDD EMI shield 100 disposed between the front bezel 130 and the back bracket 150. The HDD 200 is attached to the HDD bracket by screws 151, although other attachment methods known in the art may also be used. The HDD EMI shield 100 protects the HDD from electromagnetic interference, which is radiated or conducted energy that can disrupt or degrade performance of the HDD.

The front bezel 130 includes a bezel main body 131, latch door 135, and latch 134. When the HDD bracket 20 is disposed inside a blade server module 15 or a computer server rack 10, the 134 secures the HDD bracket 20 by latching onto an inside surface of the server module 15 or the computer server rack 10. When a release button disposed on the front surface of the front bezel 31 is pressed, the latch door 35 swings outward, and the latch 37, which is part of the latch door 35, swings inward and the HDD bracket 20 is disengaged from the blade server module 15 or the computer server rack 10. The bezel main body 131 has sloped depressions 133 on which the top fingers 101, bottom fingers 107, left fingers 103, and right fingers 109 are disposed. The top fingers 101, bottom fingers 107, left fingers 103, and right fingers 109 effectively clamp the HDD EMI shield 100 onto the bezel main body 131 of the front bezel 130. The right fingers 109 and the corresponding sloped depressions 133 are shorter to allow for the latch 134 to swing inwards.

One or more embodiments of the present invention have one or more of the following advantages. Finger-to-finger contact is allowed between HDD EMI shields 100 of HDD brackets 20 mounted on each other. Thus, the HDD brackets 20 can be mounted close together, resulting in improved storage density, while maintaining necessary HDD EMI shield finger robustness. Stronger HDD EMI shield fingers can be provided, which improves resistance to handling and insertion damage. Close-pitch placement of HDD brackets is enabled. A larger contact area between the fingers and the front bezel 130 is provided.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An electromagnetic interference shield for a hard disk drive comprising:
a metal shield portion;
a plurality of top fingers, bottom fingers, left fingers, and right fingers disposed on four sides of the metal shield portion;
bars tying the tips of the plurality of top fingers together, the tips of the plurality of bottom fingers together, the tips of the plurality of right fingers together, and the tips of the plurality of left fingers together, wherein
each of the plurality of top fingers and bottom fingers are wider than each of the plurality of left fingers and right fingers, and
each of the plurality of top fingers, bottom fingers, left fingers, and right fingers has a perpendicular jog at a base portion thereof.

2. The electromagnetic interference shield of claim 1, wherein the metal shield portion has a hexagonal tiling pattern.

3. The electromagnetic interference shield of claim 1, wherein the right fingers are shorter than the top fingers, bottom fingers, and the left fingers.

4. The electromagnetic interference shield of claim 1, further comprising apertures on one side of the metal shield portion operable to have light pipes pass through, wherein the apertures are different in shape from the metal shield portion pattern.

5. The electromagnetic interference shield of claim 1, wherein the metal shield portion is tin plated.

6. The electromagnetic interference shield of claim 1, wherein the electromagnetic interference shield is manufactured from 0.07 mm thick recyclable clean copper.

7. The electromagnetic interference shield of claim 1, wherein each of the top fingers and the bottom fingers has a length less than twice the width.

8. The electromagnetic interference shield of claim 1, wherein each of the top fingers, bottom fingers, right fingers, and left fingers are curved.

9. Electromagnetic interference shield for a hard disk drive comprising:
a metal shield portion;
a plurality of top fingers, bottom fingers, left fingers, and right fingers disposed on the four sides of the metal shield portion;
bars tying the tips of the plurality of top fingers together, the tips of the plurality of bottom fingers together, the tips of the plurality of right fingers together, and the tips of the plurality of left fingers together, wherein
each of the plurality of top fingers and bottom fingers are wider than each of the plurality of left fingers and right fingers, and
each of the plurality of top fingers, bottom fingers, left fingers, and right fingers has a perpendicular jog at a base portion thereof

10. A hard disk drive bracket comprising:
a front bezel;
a back bracket disposed behind the front bezel;
a hard disk drive disposed in the back bracket; and
an electromagnetic interference shield disposed between the front bezel and the back bracket, the electromagnetic interference shield comprising:
a metal shield portion;
a plurality of top fingers, bottom fingers, left fingers, and right fingers disposed on the four sides of the metal shield portion;
bars tying the tips of the plurality of top fingers together, the tips of the plurality of bottom fingers together, the tips of the plurality of right fingers together, and the tips of the plurality of left fingers together, wherein
each of the plurality of top fingers and bottom fingers are wider than each of the plurality of left fingers and right fingers, and
each of the plurality of top fingers, bottom fingers, left fingers, and right fingers has a perpendicular jog at a base portion thereof.

11. The hard disk drive bracket of claim 10, wherein the front bezel comprises sloped depressions on which the plurality of top fingers, bottom fingers, left fingers, and right fingers are disposed.

12. The hard disk drive bracket of claim 10, wherein
the front bezel comprises a latch door disposed on a front side of the front bezel and a latch disposed on a right side of the front bezel, operable to engage and disengage the hard disk drive bracket from a blade server module or a computer server rack, and
wherein the right fingers are shorter than the top fingers, bottom fingers, and the left fingers.

13. The hard disk drive bracket of claim 10, wherein the metal shield portion has a hexagonal tiling pattern.

14. The hard disk drive bracket of claim 10, further comprising apertures on one side of the metal shield portion operable to have light pipes pass through, wherein the apertures are different in shape from the metal shield portion pattern.

15. The hard disk drive bracket of claim 10, wherein the metal shield portion is tin plated.

16. The hard disk drive bracket of claim 10, wherein the electromagnetic interference shield is manufactured from 0.07 mm thick recyclable clean copper.

17. The hard disk drive bracket of claim 10, wherein each of the top fingers and the bottom fingers has a length less than twice the width.

18. The hard disk drive bracket of claim 10, wherein each of the top fingers, bottom fingers, right fingers, and left fingers are curved.
